(19) United States
(12) Patent Application Publication
(10) Pub. No.: US 2013/0050864 A1
(43) Pub. Date: Feb. 28, 2013

(54) Color Filter and Manufacturing Method Thereof

(71) Applicant: Hsang-Yang LIN, Yilan County (TW)

(72) Inventor: Hsang-Yang LIN, Yilan County (TW)

(73) Assignee: CHUNGHWA PICTURE TUBES, LTD., TAOYUAN (TW)

(21) Appl. No.: 13/363,363

(22) Filed: Jan. 31, 2012

(30) Foreign Application Priority Data
Aug. 23, 2011 (TW) 100130124

(51) Int. Cl. G02B 5/22; G03F 7/20

(52) U.S. Cl. 359/891; 430/7

(57) ABSTRACT

A color filter and a manufacturing method thereof are disclosed. The color filter includes a plurality of first black matrixes and a plurality of second black matrixes disposed on a substrate, and each of the second black matrixes is positioned between adjacent two of the first black matrixes. The first black matrixes define a plurality of sub-pixels, and the second black matrixes are located in the sub-pixels. A plurality of color layers are positioned in the sub-pixels, and portions of the color layers are positioned on the second black matrixes to form a plurality of protrusions.

### RELATED APPLICATIONS

This application claims priority to Taiwan Application Serial Number 100130124, filed Aug. 23, 2011 which is herein incorporated by reference.

### BACKGROUND

1. Field of Invention

The present invention relates to a color filter and a manufacturing method thereof. More particularly, the present invention relates to a color filter with improved light leakage and a manufacturing method thereof.

2. Description of Related Art

Liquid crystal displays (LCDs) are a kind of flat panel display. LCDs are widely used in various applications, especially in electronic products, since LCDs are characterized by small size, light weight, thin and low power consumption. Since the demand for LCDs are gradually increased, the demand for display quality improvement of LCDs is also increased.

LCDs are mainly assembled by two substrates, and liquid crystal molecules are filled between the two substrates. Electrodes are respectively formed on the two substrates to produce electric field to modulate the directions of the liquid crystal molecules. As electric field is applied, liquid crystal molecules may change the directions and thus adjust polarization direction of light. In fact, liquid crystal molecules do not have any colors. The colors of LCDs result from light passing through a color filter (CF). The color filter basically comprises black matrixes, three sub-pixels (red, blue, and green) and protrusions on a substrate. The protrusions are used to arrange the vertical-alignment liquid crystal molecules in a pre-tilt angle. So that, these liquid crystal molecules can be oriented along a pre-determined direction as an electric field is applied.

FIGS. 1A-1E are cross-sectional diagrams of a process for manufacturing a conventional color filter. In FIG. 1A, black matrixes 120 are formed on a substrate 110 and define a plurality of sub-pixels 125. In FIG. 1B, color layers 140 are respectively formed in the sub-pixels 125. In FIG. 1C, a transparent electrode layer 160 is formed on the black matrixes 120 and the color layers 140. In FIG. 1D, protrusions 170 are formed on the color layer 140. In FIG. 1E, spacers 180 are formed on the black matrixes 120.

The protrusions 170 on the color layers 140 may arrange the vertical alignment liquid crystal molecules in a pre-tilt angle without electric field. Most of the protrusions 170 are made from a transparent polymer resin material, such as poly-imide (PI) and etc. Therefore, when the LCD shows a black screen, light leakage can be easily observed at the sites of the protrusions 170 to decrease the contrast of the display.

### SUMMARY

Accordingly, the present disclosure directs to a method of manufacturing a color filter. The method comprises steps hereinafter. A substrate is provided. A plurality of first black matrixes and a plurality of second black matrixes are formed on the substrate, wherein the first black matrixes define a plurality of sub-pixels, and the second black matrixes each is positioned between adjacent two of the first black matrixes and located in the sub-pixel. A plurality of color layers in the sub-pixels are formed, wherein portions of the color layers are positioned on the second black matrixes to form a plurality of protrusions. A transparent electrode layer is formed on the first black matrixes and on the color layers, wherein the transparent electrode layer comprises a plurality of openings to expose the protrusions.

According to one embodiment of the present disclosure, the first black matrixes each has a first width, the second black matrixes each has a second width, and the first width is substantially larger than the second width.

According to another embodiment of the present disclosure, the first black matrixes and the second black matrixes may be formed by using the same photomask.

According to yet another embodiment of the present disclosure, the first black matrixes and the second black matrixes may be formed by using different photomasks.

According to yet another embodiment of the present disclosure, a plurality of spacers are further formed on a portion of the first black matrixes after the transparent electrode layer is formed.

The present disclosure also directs to a color filter. The color filter comprises a substrate, a plurality of first black matrixes, a plurality of second black matrixes, a plurality of color layers, and a transparent electrode layer. A plurality of first black matrixes and a plurality of second black matrixes are disposed on the substrate, wherein the first black matrixes define a plurality of sub-pixels, and the second black matrixes each is positioned between adjacent two of the first black matrixes and located in the sub-pixels. A plurality of color layers are disposed in the sub-pixels, wherein portions of the color layer positioned on the second black matrixes form a plurality of protrusion. A transparent electrode layer is positioned on the first black matrixes and the color layers, and the transparent electrode layer comprises a plurality of openings to expose the protrusions.

According to one embodiment of the present disclosure, a thickness of the second black matrixes is 1-1.5 μm.

According to another embodiment of the present disclosure, the first black matrixes each has a first width, the second black matrixes each has a second width, and the first width is substantially larger than the second width.

According to yet another embodiment of the present disclosure, the color filter further comprises spacers disposed on a portion of the first black matrixes.

According to the embodiments above, the second black matrixes are disposed in the sub-pixels to make the color layers on the second black matrixes form orientation protrusions. Since the second black matrixes can have remarkable light-shielding ability, the conventional light leakage problem of LCDs can be solved. Furthermore, since transparent resin material is not needed to form orientation protrusions, the process can be simplified to increase the yield and contrast of the LCDs.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1A-1E are cross-sectional diagrams of a process for manufacturing a conventional color filter;

FIGS. 2A-2D are cross-sectional diagrams of a process for manufacturing a color filter according to one embodiment of the present disclosure; and

FIGS. 3A-3D are cross-sectional diagrams of a process for manufacturing a color filter according to another embodiment of the present disclosure.

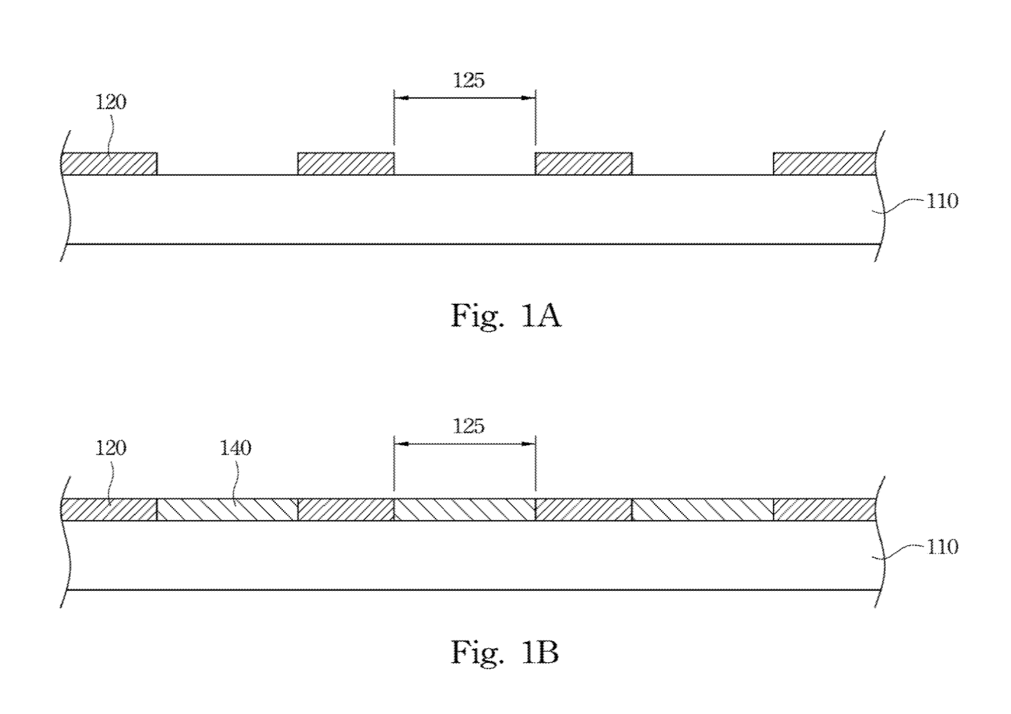

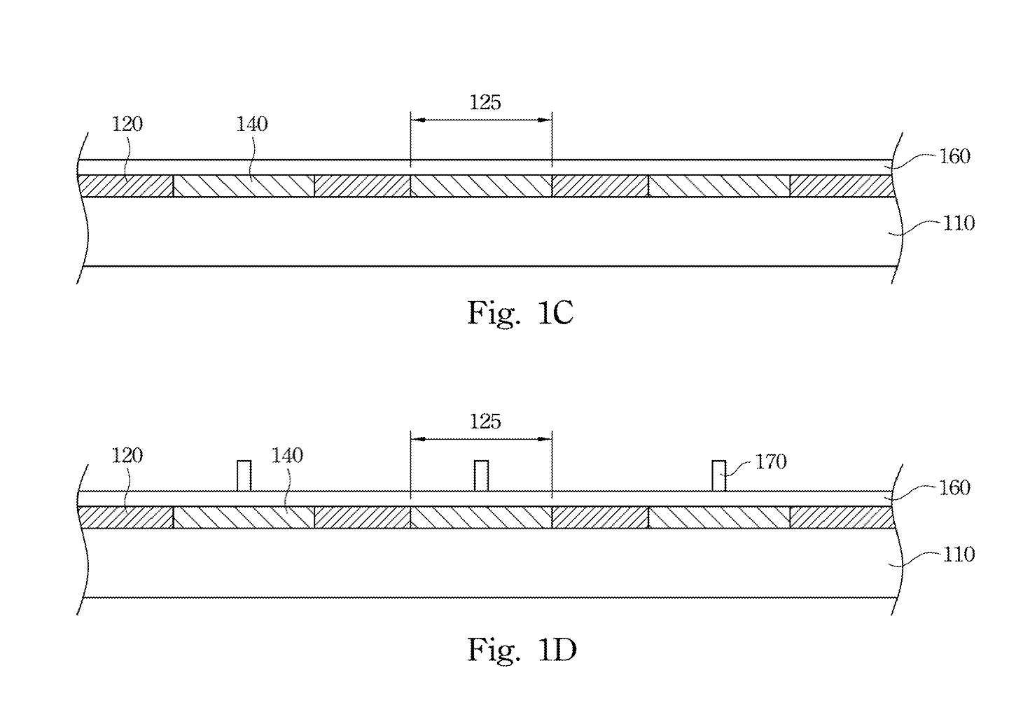

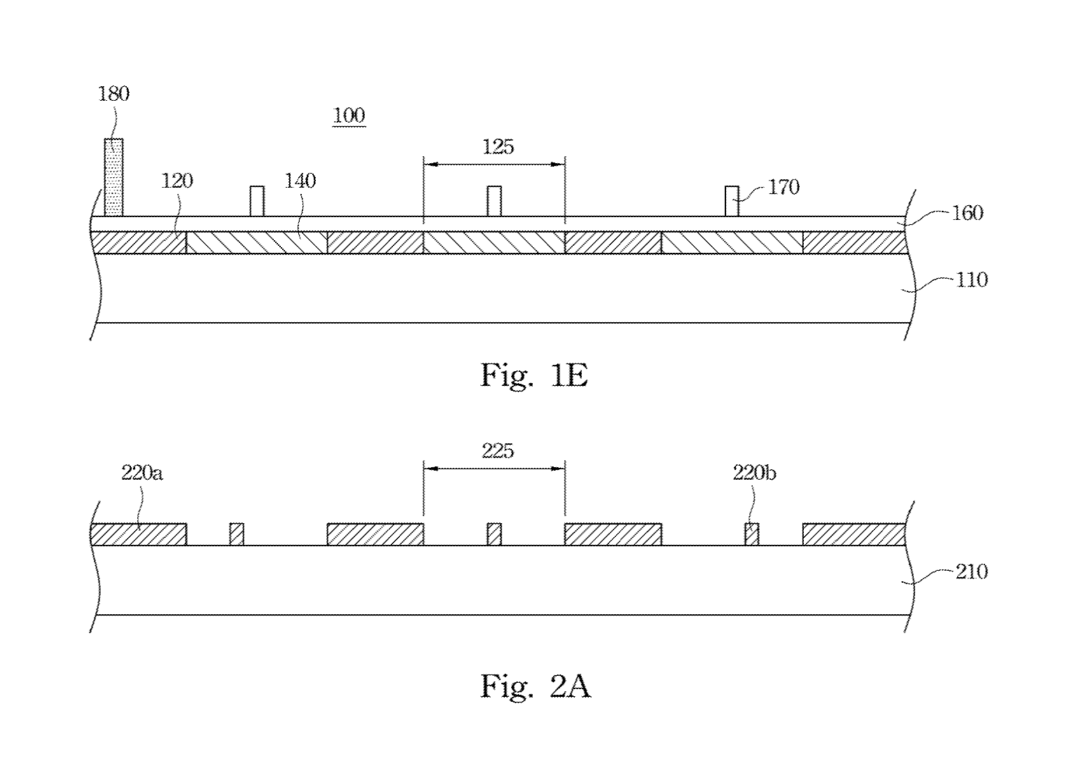

### DETAILED DESCRIPTION

Reference will now be made in detail to the embodiments of the present invention, examples of which are illustrated in the accompanying drawings. Wherever possible, the same reference numbers are used in the drawings and the description to refer to the same or like parts.

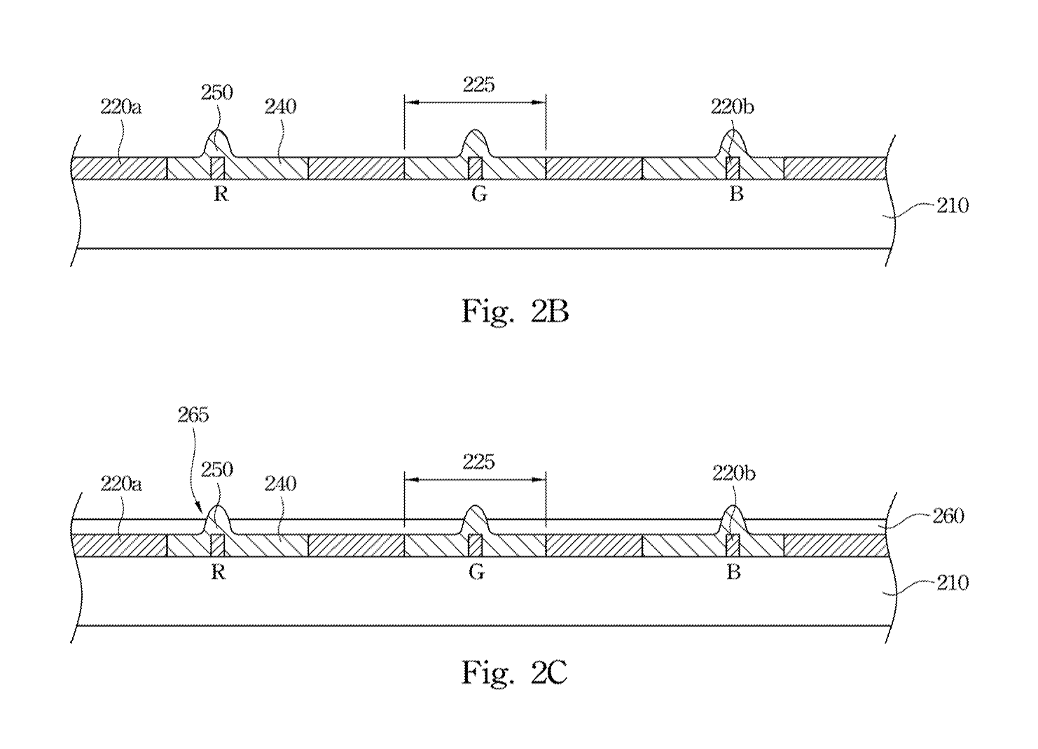

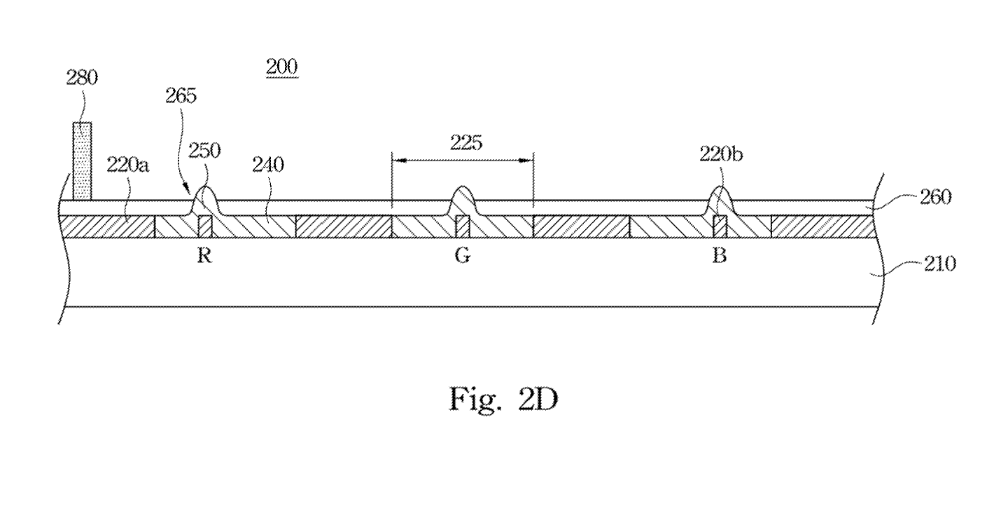

FIGS. 2A-2D are cross-sectional diagrams of a process for manufacturing a color filter according to one embodiment of the present disclosure. Referring to FIG. 2A, a plurality of first black matrixes 220a and a plurality of second black matrixes 220b are formed on the substrate 210. In particular, the black matrixes material is formed on the substrate 210, and then the first black matrixes 220a, the second black matrixes 220b and the sub-pixels 225 are defined by photolithography process, or photolithography and etching process. In this embodiment, the first black matrixes 220a and the second black matrixes 220b are formed by using the same photomask. Therefore, a thickness of the first black matrix 220a and a thickness of the second black matrix 220b are the same.

Referring to FIG. 2B, the color layers 240 are fabricated in the sub-pixels 225, and portions of the color layers 240 positioned on the second black matrixes 220b form protrusions 250. In this step, red (R) sub-pixels, green (G) sub-pixels and blue (B) sub-pixels may be respectively formed in the sub-pixels 225. In some embodiments, red (R) sub-pixels, green (G) sub-pixels, and blue (B) sub-pixels may be formed in sequence or in various orders.

Referring to FIG. 2C, a transparent electrode layer 260 is formed on the first black matrixes 220a and the color layers 240, and the openings 265 are formed at sites of the protrusions 250 to expose the protrusions 250. In some embodiments, the transparent electrode layer 260 may be formed by physical vapor deposition process or chemical vapor deposition. In one example, the transparent electrode layer 260 may be antimony-doped tin dioxide (SnO₂:Sb) layer formed by chemical vapor deposition. The openings 265 exposing the protrusions 250 may be formed by photolithography and etching processes.

Referring to FIG. 2D, the spacers 280 are formed on a portion of the first black matrixes 220a. In this step, a layer of a photosensitive material is formed by spin-coating, and a portion of the photosensitive material positioned on the sub-pixels 225 and the second black matrixes 220b are then removed by photolithography process.

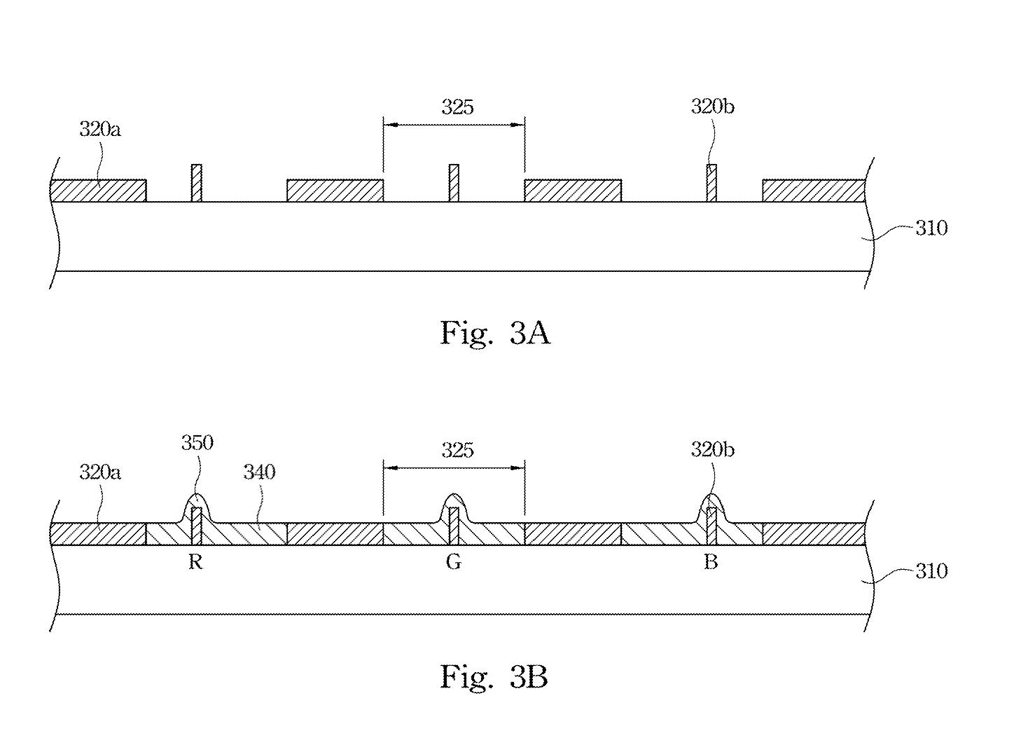

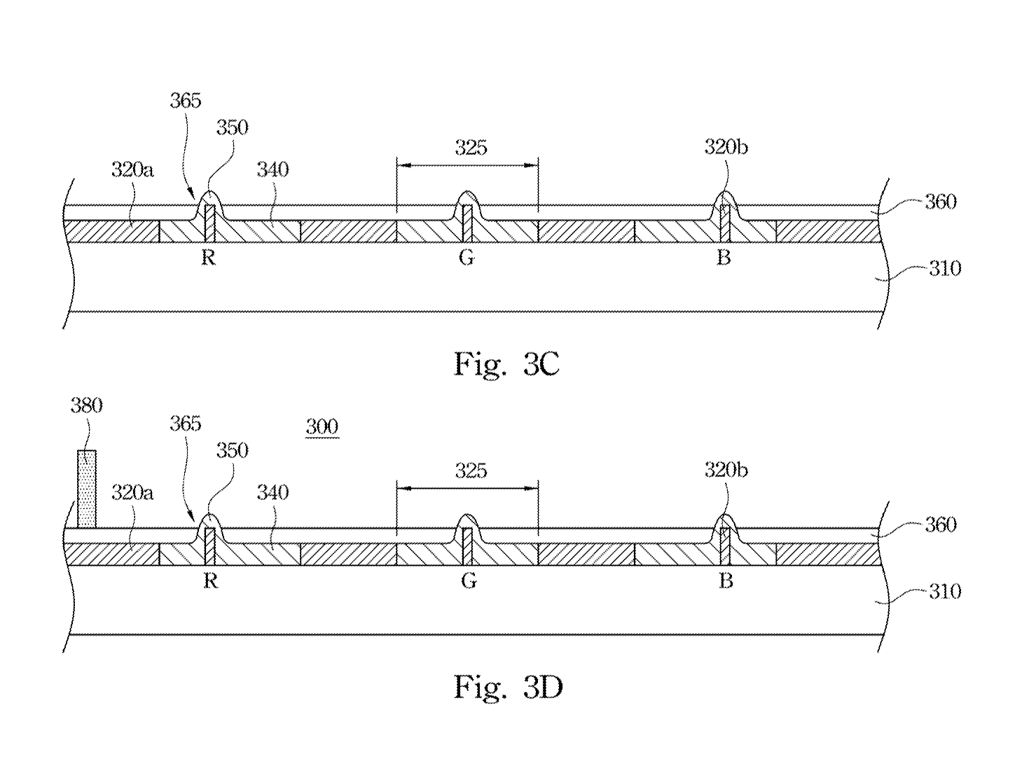

FIGS. 3A-3D are cross-sectional diagrams of a process for manufacturing a color filter according to another embodiment of the present disclosure. Referring to FIG. 3A, a plurality of first black matrixes 320a and a plurality of second black matrixes 320b are formed on the substrate 310. In this step, a black matrixes material is formed on the substrate, and then the first black matrixes 320a, the second black matrixes 320b and the sub-pixels 325 are defined by photolithography process, or photolithography and etching process. In this embodiment, the first black matrixes 320a and the second black matrixes 320b are formed by using different photomasks. Therefore, the thickness of the first black matrixes 320a and the thickness of the second black matrixes 320b are different. In one embodiment, the thickness of the second black matrixes 320b is greater than the thickness of the first black matrixes 320a. In other embodiment, the thickness of the second black matrixes 320b is smaller or equals to the thickness of the first black matrixes 320a.

Referring to FIG. 3B, the color layers 340 are fabricated in the sub-pixels 325, and portions of the color layers 340 positioned on the second black matrixes 320b form a plurality of protrusions 350. In this step, red (R) sub-pixels, green (G) sub-pixels and blue (B) sub-pixels may be respectively formed in the sub-pixels 325 by repeating a spin-coating process, a photolithography and an etching process, or by repeating a printing process. In some embodiments, red (R) sub-pixels, green (G) sub-pixels and blue (B) sub-pixels may be formed in sequence or in various orders.

Referring to FIG. 3C, a transparent electrode layer 360 is formed on the first black matrixes 320a and the color layers 340, and the openings 365 are formed at sites of the protrusions 350 to expose the protrusions 350. In some embodiments, the transparent electrode layer 360 may be formed by physical vapor deposition or chemical vapor deposition. In one example, the transparent electrode layer 360 may be antimony-doped tin dioxide (SnO₂:Sb) layer formed by chemical vapor deposition. The openings 365 of the transparent electrode layer 260 positioned at the protrusions 350 may be formed by photolithography and etching process.

Referring to FIG. 3D, the spacers 380 are formed on a portion of the first black matrixes 320a. In this step, a layer of a photosensitive material is formed by spin-coating, and portions of the photosensitive material positioned on the sub-pixels 325 and the second black matrixes 320b are then removed by photolithography process.

Referring to FIG. 2D, which is a cross-sectional diagram of the color filter 200 according to one embodiment of the present disclosure. The color filter 200 comprises the substrate 210, the first black matrixes 220a, the second black matrixes 220b, the color layers 240, the protrusions 250, the transparent electrode layer 260 and the spacers 280.

The substrate 210 may be formed by transparent material. According to one embodiment of the present disclosure, the transparent material may be glass or quartz. the first black matrixes 220a are disposed on the substrate 210 to define a plurality of sub-pixels 225. The first black matrixes 220a may be, but not limited to black photosensitive resin, electroless plating nickel, graphite or chromium.

The second black matrixes 220b are positioned on the substrate 210, and each of the second black matrixes 220b is positioned between adjacent two of the first black matrixes 220a and located in the sub-pixels 225. In one or more embodiments, the second black matrixes 220b may be located in the middle, left central, or right central part of the sub-pixels 225. In one embodiment, the second black matrixes 220b may be formed by the same material as the first black matrixes 220a.

A width of the first black matrixes 220a is substantially greater than a width of the second black matrixes 220b. In one or more embodiments, each of the second black matrixes 220b may have various widths or the same width. In this embodiment, the thickness of the second black matrixes 220b and the thickness of the first black matrixes 220a are the same. In particular, the second black matrixes 220b may have the thickness of about 1-1.5 μm.

The color layers 240 are disposed in the sub-pixels 225, and portions of the color layers 240 on the second black matrixes 220b form a plurality of protrusions 250. The color layers 240 may comprise red (R) sub-pixels, green (G) sub-pixels, and blue (B) sub-pixels, in which they may respectively comprise red pigment, green pigment and blue pigment. The color layers 240 may be formed in the sub-pixels 225 by photolithography process, or printing process.

The transparent electrode layer 260 covers the first black matrixes 220a and the color layers 240. The transparent electrode layer 260 comprises a plurality of openings 265 to expose the protrusions 250. The transparent electrode layer 260 may be made from indium tin oxides (ITO), indium zinic oxides (IZO), or antimony doped tin oxide (SnO2:Sb).

The color filter 200 further comprises the spacers 280 disposed on a portion of the first black matrixes 220a. The spacers 280 may be made from photosensitive materials. A shape of the spacer 280 may be, but not limited to square, trapezoidal, or rectangular.

Referring to FIG. 3D, which is a cross-sectional diagram of a color filter 300 according to another embodiment of the present disclosure. The color filter 300 comprises the substrate 310, the first black matrixes 320a, the second black matrixes 320b, the color layers 340, the protrusions 350, the transparent electrode layer 360, and the spacer 380. In particular, the substrate 310, the first black matrixes 320a, the color layers 340, and the transparent electrode layer 360 are respectively the same as the above-mentioned substrate 210, the first black matrixes 220a, the color layers 240, and the transparent electrode layer 260, and therefore the detail description of those elements are omitted here.

Each of the second black matrixes 320b is positioned between adjacent two of the first black matrixes 320a and located in the sub-pixels 325. In this embodiment, the second black matrixes 320b and the first black matrixes 320a have different thicknesses. For example, the second black matrixes 320b may have a thickness larger or smaller than the first black matrixes 320a.

According to the embodiments above, the second black matrixes are disposed in the sub-pixels to make the color layers on the second black matrixes form orientation protrusions. Since the second black matrixes can have remarkable light-shielding ability, the conventional light leakage problem of LCDs can be solved. Furthermore, since transparent resin material is not needed to form orientation protrusions, the process can be simplified to increase the yield and contrast of the LCDs.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method of manufacturing a color filter, comprising
providing a substrate;
forming a plurality of first black matrixes and a plurality of second black matrixes on the substrate, wherein the first black matrixes define a plurality of sub-pixels, and the second black matrixes each is positioned between adjacent two of the first black matrixes and located in the sub-pixel;
forming a plurality of color layers in the sub-pixels, wherein portions of the color layers positioned on the second black matrixes form a plurality of protrusions; and
forming a transparent electrode layer on the first black matrixes and on the color layers, wherein the transparent electrode layer comprises a plurality of openings to expose the protrusions.

2. The method of claim 1, wherein a thickness of the second black matrixes is 1-1.5 μm.

3. The method of claim 1, wherein the first black matrixes each has a first width, the second black matrixes each has a second width, and the first width is substantially larger than the second width.

4. The method of claim 1, wherein the first black matrixes and the second black matrixes are formed by using the same photomask.

5. The method of claim 1, wherein the first black matrixes and the second black matrixes are formed by using different photomasks.

6. The method of claim 1, further comprising forming a plurality of spacers on a portion of the first black matrixes after the transparent electrode layer is formed.

7. A color filter, comprising
a substrate;
a plurality of first black matrixes and a plurality of second black matrixes disposed on the substrate, wherein the first black matrixes define a plurality of sub-pixels, and the second black matrixes each is positioned between adjacent two of the first black matrixes and located in the sub-pixels;
a plurality of color layers disposed in the sub-pixels, wherein portions of the color layers positioned on the second black matrixes form a plurality of protrusions; and
a transparent electrode layer positioned on the first black matrixes and the color layers, wherein the transparent electrode layer comprises a plurality of openings to expose the protrusions.

8. The color filter of claim 7, wherein a thickness of the second black matrixes is 1-1.5 μm.

9. The color filter of claim 7, wherein the first black matrixes each has a first width, the second black matrixes each has a second width, and the first width is substantially larger than the second width.

10. The color filter of claim 7, further comprising a plurality of spacers disposed on a portion of the first black matrixes.
